(19) United States
(12) Patent Application Publication
(10) Pub. No.: US 2010/0219507 A1
(43) Pub. Date: Sep. 2, 2010

(54) PROCESS FOR PRODUCING SEMICONDUCTOR DEVICE

(76) Inventors: Sadahito Misumi, Osaka (JP); Takeshi Matsumura, Osaka (JP); Naohide Takamoto, Osaka (JP); Tsubasa Miki, Osaka (JP)

Correspondence Address: KNOBBE MARTENS OLSON & BEAR LLP, 2040 MAIN STREET, FOURTEENTH FLOOR, IRVINE, CA, 92614, US

(21) Appl. No.: 12/279,633

(22) PCT Filed: Feb. 15, 2007
(86) PCT No.: PCT/JP2007/052750

§ 371 Date: Aug. 15, 2008

(30) Foreign Application Priority Data
Feb. 16, 2006 (JP) 2006-039681

(51) Int. Cl. H01L 23/00; B32B 7/12; H01L 21/78

(52) U.S. Cl. 257/618; 428/343; 438/464; 257/E21.599; 257/E23.001

(57) ABSTRACT

According to the invention, a process for producing a semiconductor device using an adhesive sheet for a spacer, comprising preparing an adhesive sheet having a spacer layer provided with an adhesive layer on at least one surface thereof as the adhesive sheet for a spacer, a step of sticking the adhesive sheet for a spacer onto a dicing sheet with the adhesive layer as a sticking surface, a step of dicing the adhesive sheet for a spacer to form a chip-shaped spacer provided with the adhesive layer, a step of peeling the spacer from the dicing sheet together with the adhesive layer, and a step of fixing the spacer onto an adherend with the adhesive layer interposed therebetween.

### TECHNICAL FIELD

The present invention relates to a process for producing a semiconductor device using an adhesive sheet for a spacer, the adhesive sheet for a spacer used in the process, and a semiconductor device obtained by the process.

### BACKGROUND ART

In order to meet the request that semiconductor devices are made finer and caused to have higher functions, the wiring width of power supply lines arranged in the entire area of the main faces of their semiconductor chips (semiconductor elements) or the interval between signal lines arranged therein has been becoming narrower. For this reason, the impedance thereof increases or signals between signal lines of different nodes interfere with each other so as to cause hindrance to the exhibition of sufficient performances for the operation speed of the semiconductor chips, the margin of the operating voltage thereof, the resistance thereof against damage by electrostatic discharge, and others. In order to solve these problems, for example, in Patent Document 1 and Patent Document 2, package structures wherein semiconductor elements are laminated are suggested.

As a material used to stick semiconductor elements to a substrate or the like, the following examples are suggested: an example wherein a thermosetting paste resin is used (see, for example, Patent Document 3); and examples wherein an adhesive sheet composed of a thermoplastic resin and a thermosetting resin is used (see, for example, Patent Document 4).

In the conventional process for producing a semiconductor device, when a paste rein is used for the adhesion of a semiconductor element with a substrate, a lead frame, or a semiconductor element (referred to as substrate, etc., hereinafter), it is pointed out that the paste resin is pushed out after pressure bonding the semiconductor element with the substrate, etc., (die attaching), and contaminates a connection pad part of the substrate, etc., and thus a wire bonding cannot be performed.

Therefore, in order to avoid the above-described problems, examples of using an adhesive sheet has increased recently. In the case of using this adhesive sheet, a semiconductor chip is generally formed by sticking an adhesive sheet onto a semiconductor wafer, and then performing dicing of the semiconductor wafer. Further, there is a case of laminating, on the semiconductor chip, another semiconductor chip with the same size using such an adhesive sheet, to perform three-dimensional mounting. Here, in order to be able to laminate, on a semiconductor chip, another semiconductor chip with the same size, it is necessary to laminate a spacer between the semiconductor chips. This is because the other semiconductor chip may be laminated also on an electrode pad part in the semiconductor chip. For example, an adhesive sheet or a chip with an adhesive sheet is used as the spacer.

However, in the case of using an adhesive sheet as this spacer, it is necessary to stick the adhesive sheet onto the semiconductor chip. However, this step cannot be performed in conventional equipment. Therefore, novel equipment for sticking the adhesive sheet becomes necessary, and it invites high cost in the production facility. Further, in the case of using a chip with an adhesive sheet as the spacer, it is necessary to stick a semiconductor wafer with the adhesive sheet and to perform die-attaching after dicing it. However, when a laminated semiconductor device is produced in such a step, the yield decreases because the semiconductor chip that is used is easily broken. As a result, decrease in productivity of the semiconductor device and high cost become problems.

Patent Document 1: Japanese Unexamined Patent Publication S55-111151

Patent Document 2: Japanese Unexamined Patent Publication 2002-261233

Patent Document 3: Japanese Unexamined Patent Publication 2002-179769

Patent Document 4: Japanese Unexamined Patent Publication 2000-104040

### DISCLOSURE OF THE INVENTION

### Problems to be Solved by the Invention

The present invention has been made in view of the above-described problems, and an object of the present invention is to provide a process for producing a semiconductor device that can perform three-dimensional mounting of a spacer onto an adherend in the same manner as a conventional process using an adhesive sheet for a spacer, and as a result, can be produced at high yield and low cost, the adhesive sheet for a spacer that is used in the production process, and a semiconductor device obtained by the production process.

### Means for Solving the Problems

In order to solve the above-mentioned problems, the present inventors have made eager investigations on a process for producing semiconductor device, adhesive sheets used in the process, and semiconductor devices obtained by the process. As a result, the inventors find out that the above-mentioned object can be attained by adopting a configuration that will be described below, to complete the invention.

That is, the present invention relates to a process for producing a semiconductor device using an adhesive sheet for a spacer, comprising preparing an adhesive sheet having a spacer layer provided with an adhesive layer on at least one surface thereof as the adhesive sheet for a spacer, a step of sticking the adhesive sheet for a spacer onto a dicing sheet with the adhesive layer as a sticking surface, a step of dicing the adhesive sheet for a spacer to form a chip-shaped spacer provided with the adhesive layer, a step of peeling the spacer from the dicing sheet together with the adhesive layer, and a step of fixing the spacer onto an adherend with the adhesive layer interposed therebetween.

Accordingly, the present invention relates to a process for producing a semiconductor device using an adhesive sheet for a spacer, comprising preparing a sheet, in which a pressure-sensitive adhesive layer, an adhesive layer, and a spacer layer are laminated one by one, for the adhesive sheet for a spacer, a step of dicing the adhesive sheet for a spacer to form a chip-shaped spacer provided with the adhesive layer, a step of peeling the spacer from the pressure-sensitive adhesive layer together with the adhesive layer, and a step of fixing the spacer onto an adherend with the adhesive layer interposed therebetween.

According to each of the production processes described above, it becomes possible to mount a chip-shaped spacer onto an adherend using the same process and equipment as in the formation of a semiconductor chip by the dicing of a semiconductor wafer, the pickup of the semiconductor chip, and the die-bonding of the semiconductor chip onto the adherend that have been conventionally performed. As a result, novel equipment for fixing the spacer onto the adherend becomes unnecessary, and it becomes possible to produce a semiconductor device while suppressing high cost in a production facility.

In the above-described process, the above-described adhesive sheet for a spacer is preferably used in which the spacer layer is a metal layer. In the case of using a semiconductor chip with an adhesive layer as a spacer, chipping, or the like, occurs during dicing for example because the semiconductor chip is easily broken. For this reason, when the semiconductor chip is used as the spacer, the yield decreases. However, when the spacer layer is a metal layer as in the above-described process, the yield can be attempted to be improved because cracking, or the like, does not occur in the metal layer.

In the above-described process, the adherend is preferably a substrate, a lead frame, or other semiconductor elements. In the process, it becomes possible to stick the semiconductor element on the spacer with the adhesive layer interposed therebetween, and the yield is improved and the three-dimensional mounting of the semiconductor element becomes possible even in the case of using the adhesive sheet for a spacer.

It is preferred to use, as the adhesive sheet, a sheet including a thermoplastic resin.

It is preferred to use, as the adhesive sheet, a sheet including both of a thermosetting resin and a thermoplastic resin.

It is preferred to use, as the thermoplastic resin, an acrylic resin. The acrylic resin contains only a small amount of ionic impurities, and has a high heat resistance. Thus, the reliability of the semiconductor element can be certainly kept.

Further, the adhesive sheet for a spacer according to the present invention is characterized by being used in the above-described process for producing a semiconductor device in order to solve the above-described problems.

In order to solve the above-mentioned problems, the semiconductor device according to the present invention is a semiconductor device obtained by the above-mentioned process for producing semiconductor device.

### EFFECTS OF THE INVENTION

The invention produces the following advantageous effects by the above-mentioned process, sheet and device.

That is, according to the present invention, because it becomes possible to mount a chip-shaped spacer onto an adherend using the same process in the formation of a semiconductor chip by the dicing of a semiconductor wafer, the pickup of the semiconductor chip, and the die-bonding of the semiconductor chip onto the adherend that have been conventionally performed, novel equipment for fixing the spacer onto the adherend becomes unnecessary, and it becomes possible to produce a semiconductor device while suppressing high cost in a production facility.

### BRIEF DESCRIPTION OF THE DRAWINGS

FIG. 1 is a cross-sectional schematic view showing an outline of an adhesive sheet for a spacer used in a process for producing a semiconductor device according to the present invention.

FIG. 2 is a process view illustrating the process for producing a semiconductor device using the adhesive sheet for a spacer.

FIG. 3 is a cross-sectional view showing an outline of the semiconductor device obtained by the process for producing a semiconductor device.

FIG. 4 is a process view illustrating a dicing step of an adhesive sheet for a spacer that is used in an embodiment 2 of the present invention.

FIG. 5 is a cross-sectional view showing an outline of the semiconductor device obtained by the process for producing a semiconductor using the adhesive sheet for a spacer.

### DESCRIPTION OF THE REFERENCE NUMERALS

1 base film
2 pressure-sensitive adhesive layer
3 adhesive layer
4 spacer layer
5 adhesive layer
10-12 adhesive sheet
14,15 chip-shaped spacer
16 bonding wire
21 bonding layer
22 semiconductor wafer
23 semiconductor chip
31 supporting substrate
32 pressure-sensitive adhesive layer
33 dicing tape
34 adherend

### BEST MODE FOR CARRYING OUT THE INVENTION

### Embodiment 1

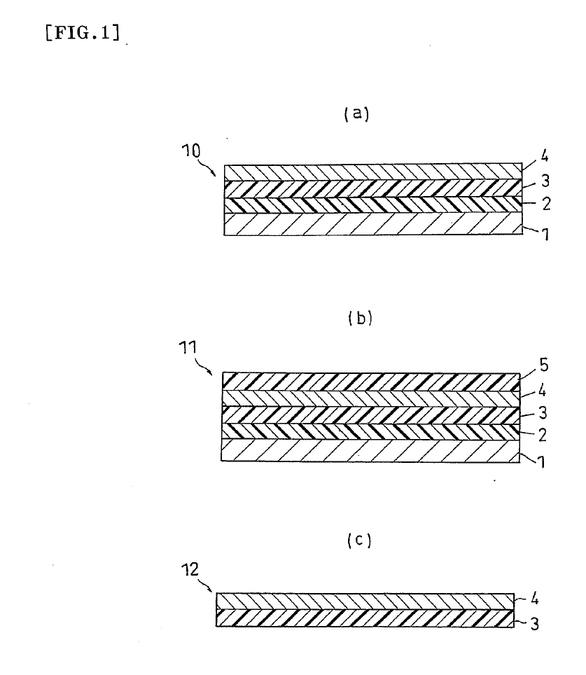

An embodiment of the present invention is described below with reference to the drawings. FIG. 1 is a cross-sectional schematic view showing a step of producing a chip-shaped spacer using an adhesive sheet for a spacer (hereinafter, simply referred to as “adhesive sheet”) according to the present embodiment.

As shown in FIG. 1(a), an adhesive sheet 10 according to the present embodiment has a configuration in which a pressure-sensitive adhesive layer 2, an adhesive layer 3, and a spacer layer 4 are laminated on a base film 1 in this order. A laminated part consisting of the base film 1 and the pressure-sensitive adhesive layer 2 functions as a dicing sheet. However, the present invention is not limited to this embodiment, and it may have a configuration, in which another adhesive layer 5 is laminated on the spacer layer 4 as in an adhesive sheet 11 shown in FIG. 1(b), or a configuration, in which the adhesive layer 3 is laminated on at least one surface of the spacer layer 4 as in an adhesive sheet 12 shown in FIG. 1(c).

The spacer layer 4 is not especially limited. However, the spacer layer 4 preferably has rigidity at least equal to or more than that of a semiconductor wafer having nearly the same thickness as in the spacer layer. An example of such a spacer layer 4 includes a metal layer made of a metal foil, etc. When the spacer layer 4 is a metal layer, cracking, or the like, does not occur during the dicing, the pickup, or the die-bonding described below, which occur in the case of using a semiconductor chip as a spacer. For this reason, the improvement of the yield can be attempted. Materials for the metal foil are not especially limited. Specific examples thereof include a metal foil made of copper, a copper alloy, stainless steel, a stainless steel alloy, nickel, a nickel alloy (including a 42 alloy), aluminum, or an aluminum alloy. Further, in the case of generally using a copper foil, copper foils such as a rolled steel foil and an electrolytic steel foil can be often used, and these copper foils can be preferably used also in the present invention. Moreover, a corrosion-preventing layer and a heat-resistant layer can be applied to the surface of these metal foils.

The thickness of the spacer layer 4 is not especially limited. However, if the thickness of the spacer layer 4 is too thick, the thickness of the semiconductor device becomes thick, and there is a case that the production of a thin semiconductor device is difficult. On the other hand, if the thickness of the spacer layer 4 becomes too thin, there is a case that its self-supporting property becomes insufficient and its handling property decreases. For this reason, the thickness of the spacer layer 4 is preferably in the range of 5 to 100 μm.

Further, the ratio of the thickness of the spacer layer 4 to the total thickness of the adhesive sheets 10 to 12 ((Thickness of the Spacer Layer 4)/(Total Thickness of the Adhesive Layers 10 to 12)) is preferably in the range of 0.1 to 0.99, and more preferably 0.3 to 0.95. When this ratio is less than 0.1, there is a case that the pickup workability decreases because the space layer 4 is too thin. Further, when this ratio exceeds 0.99, the thickness of the adhesive sheets 10 to 12 becomes too thin, and sufficient adhesive strength cannot be realized.

The adhesive layer 3 is a layer having an adhesive function, and the constituent material thereof may be a material composed of a thermoplastic resin and a thermosetting resin, or a material made only of a thermoplastic resin.

Examples of the thermoplastic resin include natural rubber, butyl rubber, isoprene rubber, chloroprene rubber, ethylene/vinyl acetate copolymer, ethylene/acrylic acid copolymer, ethylene/acrylic ester copolymer, polybutadiene resin, polycarbonate resin, thermoplastic polyimide resin, polyamide resins such as 6-nylon (registered trademark) and 6,6-nylon (registered trademark), phenoxy resin, acrylic resin, saturated polyester resins such as PET and PBT, polyamideimide resin, and fluorine-contained resin. These thermoplastic resins may be used alone or in combination of two or more thereof. Of these thermoplastic resins, acrylic resin is particularly preferable since the resin contains ionic impurities in only a small amount and has a high heat resistance so as to make it possible to ensure the reliability of the semiconductor element.

The acrylic resin is not limited to any especial kind, and may be, for example, a polymer comprising, as a component or components, one or more esters of acrylic acid or methacrylic acid having a linear or branched alkyl group having 30 or less carbon atoms, in particular, 4 to 18 carbon atoms. Examples of the alkyl group include methyl, ethyl, propyl, isopropyl, n-butyl, t-butyl, isobutyl, amyl, isoamyl, hexyl, heptyl, cyclohexyl, 2-ethylhexyl, octyl, isooctyl, nonyl, isononyl, decyl, isodecyl, undecyl, lauryl, tridecyl, tetradecyl, stearyl, octadecyl, and dodecyl groups.

A different monomer which constitutes the above-mentioned polymer is not limited to any especial kind, and examples thereof include carboxyl-containing monomers such as acrylic acid, methacrylic acid, carboxyethyl acrylate, carboxypentyl acrylate, itaconic acid, maleic acid, fumaric acid, and crotonic acid; acid anhydride monomers such as maleic anhydride and itaconic anhydride; hydroxyl-containing monomers such as 2-hydroxyethyl(meth)acrylate, 2-hydroxypropyl(meth)acrylate, 4-hydroxybutyl(meth)acrylate, 6-hydroxyhexyl(meth)acrylate, 8-hydroxyoctyl(meth)acrylate, 10-hydroxydecyl(meth)acrylate, 12-hydroxylauryl(meth)acrylate, and (4-hydroxymethylcyclohexyl) methylacrylate; monomers which contain a sulfonic acid group, such as styrenesulfonic acid, allylsulfonic acid, 2-(meth)acrylamide-2-methylpropanesulfonic acid, (meth)acrylamidepropane sulfonic acid, sulfopropyl(meth)acrylate, and (meth)acryloyloxynaphthalenesulfonic acid; and monomers which contain a phosphoric acid group, such as 2-hydroxyethylacryloyl phosphate.

Examples of the above-mentioned thermosetting resin include phenol resin, amino resin, unsaturated polyester resin, epoxy resin, polyurethane resin, silicone resin, and thermosetting polyimide resin. These resins may be used alone or in combination of two or more thereof. Particularly preferable is epoxy resin, which contains ionic impurities which corrode semiconductor elements in only a small amount. As the curing agent of the epoxy resin, phenol resin is preferable.

The epoxy resin may be any epoxy resin that is ordinarily used as an adhesive composition. Examples thereof include bifunctional or polyfunctional epoxy resins such as bisphenol A type, bisphenol F type, bisphenol S type, brominated bisphenol A type, hydrogenated bisphenol A type, bisphenol AF type, biphenyl type, naphthalene type, fluorene type, phenol Novolak type, orthocresol Novolak type, tris-hydroxyphenylmethane type, and tetraphenylolethane type epoxy resins; hydantoin type epoxy resins; tris-glycicylisocyanurate type epoxy resins; and glycidylamine type epoxy resins. These may be used alone or in combination of two or more thereof. Among these epoxy resins, particularly preferable are Novolak type epoxy resin, biphenyl type epoxy resin, tris-hydroxyphenylmethane type epoxy resin, and tetraphenylolethane type epoxy resin, since these epoxy resins are rich in reactivity with phenol resin as an agent for curing the epoxy resin and are superior in heat resistance and so on.

The phenol resin is a resin acting as a curing agent for the epoxy resin. Examples thereof include Novolak type phenol resins such as phenol Novolak resin, phenol aralkyl resin, cresol Novolak resin, tert-butylphenol Novolak resin and nonylphenol Novolak resin; resol type phenol resins; and polyoxystyrenes such as poly(p-oxystyrene). These may be used alone or in combination of two or more thereof. Among these phenol resins, phenol Novolak resin and phenol aralkyl resin are particularly preferable, since the connection reliability of the semiconductor device can be improved.

About the blend ratio between the epoxy resin and the phenol resin, for example, the phenol resin is blended with the epoxy resin in such a manner that the hydroxyl groups in the phenol resin is preferably from 0.5 to 2.0 equivalents, more preferably from 0.8 to 1.2 equivalents per equivalent of the epoxy groups in the epoxy resin component. If the blend ratio between the two is out of the range, curing reaction therebetween does not advance sufficiently so that properties of the cured epoxy resin easily deteriorate.

In the present invention, an adhesive sheet comprising the epoxy resin, the phenol resin, and an acrylic resin is particularly preferable. Since these resins contain ionic impurities in only a small amount and have high heat resistance, the reliability of the semiconductor element can be ensured. About the blend ratio in this case, the amount of the mixture of the epoxy resin and the phenol resin is from 10 to 200 parts by weight for 100 parts by weight of the acrylic resin component.

In order to crosslink the adhesive layer 3 of the present invention to some extent in advance, it is preferable to add, as a crosslinking agent, a polyfunctional compound which reacts with functional groups of molecular chain terminals of the above-mentioned polymer to the materials used when the adhesive layer 3 is produced. In this way, the adhesive property of the adhesive layer 3 at high temperatures is improved so as to improve the heat resistance.

The crosslinking agent may be one known in the prior art. Particularly preferable are polyisocyanate compounds, such as tolylene diisocyanate, diphenylmethane diisocyanate, p-phenylene diisocyanate, 1,5-naphthalene diisocyanate, and adducts of polyhydric alcohol and diisocyanate. The amount of the crosslinking agent to be added is preferably set to 0.05 to 7 parts by weight for 100 parts by weight of the above-mentioned polymer. If the amount of the crosslinking agent to be added is more than 7 parts by weight, the adhesive force is unfavorably lowered. On the other hand, if the adding amount is less than 0.05 part by weight, the cohesive force is unfavorably insufficient. A different polyfunctional compound, such as an epoxy resin, together with the polyisocyanate compound may be incorporated if necessary.

An inorganic filler may be appropriately incorporated into the adhesive layer 3 of the present invention in accordance with the use purpose thereof. The incorporation of the inorganic filler makes it possible to confer electric conductance to the sheet, improve the thermal conductivity thereof, and adjust the elasticity. Examples of the inorganic fillers include various inorganic powders made of the following: a ceramic such as silica, clay, plaster, calcium carbonate, barium sulfate, aluminum oxide, beryllium oxide, silicon carbide or silicon nitride; a metal such as aluminum, copper, silver, gold, nickel, chromium, lead, tin, zinc, palladium or solder, or an alloy thereof; and carbon. These may be used alone or in combination of two or more thereof. Among these, silica, in particular fused silica is preferably used. The average particle size of the inorganic filler is preferably from 0.1 to 80 μm.

The amount of the inorganic filler to be incorporated is preferably set into the range of 0 to 80 parts by weight (more preferably, 0 to 70 parts by weight) for 100 parts by weight of the organic resin components.

If necessary, other additives besides the inorganic filler may be incorporated into the adhesive sheet 12 of the present invention. Examples thereof include a flame retardant, a silane coupling agent, and an ion trapping agent.

Examples of the flame retardant include antimony trioxide, antimony pentaoxide, and brominated epoxy resin. These may be used alone or in combination of two or more thereof.

Examples of the silane coupling agent include β-(3,4-epoxycyclohexyl)ethyltrimethoxysilane, γ-glycidoxypropyltrimethoxysilane, and γ-glycidoxypropylmethyldiethoxysilane. These may be used alone or in combination of two or more thereof.

Examples of the ion trapping agent include hydrotalcite and bismuth hydroxide. These may be used alone or in combination of two or more thereof.

The base film 1 confers strength on the dicing die-bonding film 10, 11. Examples of the base film include polyolefins such as low-density polyethylene, linear polyethylene, middle-density polyethylene, high-density polyethylene, ultra-low-density polyethylene, random copolymerization polypropylene, block copolymerization polypropylene, homopolypropylene, polybutene, polymethyl pentene etc., polyesters such as ethylene/vinyl acetate copolymer, ionomer resin, ethylene/(meth)acrylic acid copolymer, ethylene/(meth)acrylate (random, alternating) copolymer, ethylene/butane copolymer, ethylene/hexene copolymer, polyurethane, polyethylene terephthalate, polyethylene naphthalate etc., polycarbonate, polyimide, polyether ether ketone, polyimide, polyether imide, polyamide, every aromatic polyamide, polyphenyl sulfide, aramid (paper), glass, glass cloth, fluorine resin, polyvinyl chloride, polyvinylidene chloride, cellulose resin, silicone resin, metal (foil), paper etc. The material of the substrate material includes polymers such as those crosslinked from the resin described above. The exemplary material constituting the substrate material may be used after grafting a functional group, a functional monomer or a modifying monomer onto it if necessary.

Further, an example of a material of the base film 1 is a polymer such as a crosslinked body of the above-described resins. When the base film 1 is composed of a plastic film, the plastic film may be used in a non-stretched form or after subjection if necessary to uniaxial or biaxial stretching treatment. According to a resin sheet endowed with thermal shrinkability by stretching treatment, the base film 1 can be thermally shrunk after dicing thereby reducing the contact area between the pressure-sensitive adhesive layer 2 and the adhesive layer 3 to facilitate the recovery of chipped works.

The surface of the base film 1 can be subjected to ordinary surface treatment for improving adhesion and maintenance of the adjacent layer, for example chemical or physical treatment such as treatment with chromate, exposure to ozone, exposure to flames, high-voltage electric shock exposure, and treatment with ionization radiations, or coating treatment with a undercoat (for example, a sticky material described later).

The same or different kinds of the base film 1 can be suitably selected and used. The substrate material may be a single layer or multilayer or may be a blend substrate material having two or more kinds of resins dry-blended therein. The multilayer film can be produced from the above resin etc. by a conventional film lamination method such as co-extrusion method, dry lamination method etc. The base film 1 can be provided thereon with a evaporated layer of about 30 to 500 Å consisting of an electroconductive material such as a metal, an alloy and an oxide thereof in order to confer antistatic performance. The base film 1 may be a single layer or a multilayer consisting of two or more layers. When the pressure-sensitive adhesive layer 2 is a radiation-curing adhesive layer, the substrate material permitting radiations such as X-ray, UV ray, electron beam etc. to pass therethrough at least partially is used.

The thickness of the base film 1 can be suitably determined without particular limitation, and is generally preferably about 5 to 200 μm.

The pressure-sensitive adhesive used in the formation of the pressure-sensitive adhesive layer 2 is not especially limited, and a general pressure sensitive adhesive such as an acrylic pressure-sensitive adhesive and a rubber pressure-sensitive adhesive can be used for example. The above-described pressure sensitive adhesive is preferably an acrylic pressure-sensitive adhesive having an acrylic polymer as a base polymer in terms of the cleaning and washing property by super-pure water and an organic solvent such as alcohol of electronic parts such as a semiconductor wafer and glass, in which contamination is disliked.

The acrylic polymer includes, for example, acrylic polymers using, as a monomer component, one or more of alkyl(meth)acrylates (for example, C1 to C30, particularly C4 to C18, linear or branched alkyl esters such as methyl ester, ethyl ester, propyl ester, isopropyl ester, butyl ester, isobutyl ester, s-butyl ester, t-butyl ester, pentyl ester, isopentyl ester, hexyl ester, heptyl ester, octyl ester, 2-ethylhexyl ester, isooctyl ester, nonyl ester, decyl ester, isodecyl ester, undecyl ester, dodecyl ester, tridecyl ester, tetradecyl ester, hexadecyl ester, octadecyl ester, eicosyl ester etc.) and cycloalkyl (meth)acrylates (for example, cyclopentyl ester, cyclohexyl ester etc.). The (meth)acrylates refer to acrylates and/or methacrylates, and the term “(meth)” in the present invention is all used in this meaning. From the viewpoint of adhesion and release, the acrylic polymer preferably has a glass transition temperature of −70° C. or more, more preferably −60° C. or more, still more preferably −40° C. to −10° C. Accordingly, the main monomer forming the acrylic polymer is preferably a monomer giving a homopolymer having a glass transition temperature of −70° C. or more.

If necessary, the acrylic polymer may contain units corresponding to other monomer components copolymerizable with the alkyl(meth)acrylate or cycloalkyl ester, for the purpose of modification of flocculation, heat resistance etc. Such monomer components include, for example, carboxyl group-containing monomers such as acrylic acid, methacrylic acid, carboxyethyl(meth)acrylate, carboxypentyl(meth)acrylate, itaconic acid, maleic acid, fumaric acid, crotonic acid etc.; acid anhydride monomers such as maleic anhydride, itaconic anhydride etc.; hydroxyl group-containing monomers such as 2-hydroxyethyl(meth)acrylate, 2-hydroxypropyl (meth)acrylate, 4-hydroxybutyl(meth)acrylate, 6-hydroxyhexyl(meth)acrylate, 8-hydroxyoctyl(meth)acrylate, 10-hydroxydecyl(meth)acrylate, 12-hydroxylauryl(meth)acrylate, (4-hydroxymethylcyclohexyl) methyl (meth)acrylate etc.; sulfonic acid group-containing monomers such as styrenesulfonic acid, allylsulfonic acid, 2-(meth)acrylamide-2-methylpropanesulfonic acid, (meth)acrylamide propanesulfonic acid, sulfopropyl(meth)acrylate, (meth)acryloyloxynapthalenesulfonic acid etc.; phosphate group-containing monomers such as 2-hydroxyethyl acryloyl phosphate etc.; and glycidyl (meth)acrylate, (meth)acrylamide, N-hydroxymethyl(meth)acrylamide, alkyl amino alkyl(meth)acrylate (for example, dimethylaminoethyl methacrylate, t-butylaminoethyl methacrylate etc.), N-vinyl pyrrolidone, acryloyl morpholine, vinyl acetate, styrene, acrylonitrile etc. These copolymerizable monomer components can be used alone or as a mixture of two or more thereof. The use amount of these copolymerizable monomers is preferably 40 wt % or less based on the whole monomer components.

For crosslinking, the acrylic polymer can also contain multifunctional monomers if necessary as the copolymerizable monomer component. Such multifunctional monomers include hexane diol di(meth)acrylate, (poly)ethylene glycol di(meth)acrylate, (poly)propylene glycol di(meth)acrylate, neopentyl glycol di(meth)acrylate, pentaerythritol di(meth)acrylate, trimethylol propane tri(meth)acrylate, pentaerythritol tri(meth)acrylate, dipentaerythritol hexa(meth)acrylate, epoxy(meth)acrylate, polyester (meth)acrylate, urethane (meth)acrylate etc. These multifunctional monomers can also be used as a mixture of one or more thereof. From the viewpoint of adhesiveness etc., the use amount of the multifunctional monomer is preferably 30 wt % or less based on the whole monomer components.

The acrylic polymer is obtained by subjecting a single monomer or a mixture of two or more monomers to polymerization. The polymerization can be carried out in any system such as solution polymerization, emulsion polymerization, bulk polymerization, suspension polymerization etc. From the viewpoint of preventing contamination of a clean adherend, the content of a low-molecular compound is preferably lower. In this respect, the number-average molecular weight of the acrylic polymer is preferably 300,000 or more, more preferably about 400,000 to 3,000,000.

For the above-mentioned adhesive, an external crosslinking agent may be appropriately used in order to heighten the number-average molecular weight of the acrylic polymer or the like as the base polymer. A specific example of the method of using the external crosslinking agent may be a method of adding, to the base polymer, the so-called crosslinking agent, such as a polyisocyanate compound, epoxy compound, aziridine compound or melamine type crosslinking agent, so as to cause crosslinking reaction. In the case that the external crosslinking agent is used, the amount thereof is appropriately decided in accordance with the balance with the amount of the base polymer to be crosslinked and further the use purpose of the adhesive. In general, the amount of the external cross-linking agent is preferably 5 or less parts by weight of the base polymer, more preferably about 0.1 to 5 parts by weight. If necessary, any conventional additive such as a tackifier, an antioxidant, a filler, and a colorant may be added in addition to the above components.

The pressure-sensitive adhesive layer 2 can be configured by including a radiation-curable pressure-sensitive adhesive. The radiation-curable pressure-sensitive adhesive easily decreases its adhesive strength by increasing the degree of crosslinking due to irradiation of radiation such as an ultraviolet ray. Therefore, the pressure-sensitive adhesive layer 2 can be cured by radiating radiation onto the pressure-sensitive adhesive layer 2, and thus, the pickup of the chip-shaped spacer formed by dicing can be performed easily. Moreover, in the case that the adhesive layer 3 and the spacer layer 4 are formed only on a prescribed region on the pressure-sensitive adhesive layer 2, a difference of the adhesive strength and that of another region can be provided by irradiating radiation only on the corresponding region.

Partial irradiation of radiation to the pressure-sensitive adhesive layer 2 is possible by irradiation through a photo mask, in which a corresponding pattern is formed on a region other than the above-described region. Further, a method of irradiating an ultraviolet ray in spots, and the like, are included. The formation of the radiation-curable pressure-sensitive adhesive layer 2 can be performed by transferring a layer provided on a separator onto the base film 1. The partial radiation curing can be also performed on the radiation-curable pressure-sensitive adhesive layer 2 provided on the separator.

Moreover, in the case that curing hindrance due to oxygen occurs during the irradiation of radiation, it is desirable to shut oxygen (air) from the surface of the radiation-curable pressure-sensitive adhesive layer 2. Examples of this method include a method of coating the surface of the pressure-sensitive adhesive layer 2 with a separator and a method of performing irradiation of radiation such as an ultraviolet ray in a nitrogen gas atmosphere.

As described above, in the pressure-sensitive adhesive layer 2 of the adhesive sheet 10 shown in FIG. 1(a), the above-described part formed by a non-cured radiation-curable pressure-sensitive adhesive sticks to the adhesive layer 3, and a retaining force when dicing can be secured. The radiation-curable pressure-sensitive adhesive can support the adhesive layer 3 for fixing the chip-shaped spacer to the adherend such as a substrate with good balance in adhesion and peeling in such a manner.

The radiation-curable pressure-sensitive adhesive having a radiation curable functional group such as a carbon-carbon double bond, and showing adhesiveness can be used especially without limitation. An example of the radiation-curable pressure-sensitive adhesive includes an adding type radiation-curable pressure-sensitive adhesive, in which a radiation-curable monomer component or oligomer component is compounded into a general pressure-sensitive adhesive such as the above-described acrylic adhesive and rubber adhesive.

The radiation-curing monomer component to be compounded includes, for example, polyvalent alcohol (meth)acrylates such as trimethylol propane tri(meth)acrylate, tetramethylol methane tetra(meth)acrylate, pentaerythritol tri(meth)acrylate, pentaerythritol tetra(meth)acrylate, dipentaerythritol monohydroxy penta(meth)acrylate, dipentaerythritol hexa(meth)acrylate, 1,4-butane diol di(meth)acrylate, tetraethylene glycol di(meth)acrylate, 1,6-hexane diol (meth)acrylate, neopentyl glycol di(meth)acrylate etc.; ester acrylate oligomers; and isocyanurates or isocyanurate compounds such as 2-propenyl-3-butenyl cyanurate, tris(2-methacryloxyethyl) isocyanurate etc. The radiation-curing oligomer component includes various acrylate oligomers such as those based on urethane, polyether, polyester, polycarbonate, polybutadiene etc., and their molecular weight is preferably in the range of about 100 to 30000. For the compounded amount of the radiation-curable monomer component or oligomer component, the amount of which the adhesive strength of the pressure-sensitive adhesive layer can be decreased can be determined appropriately depending on the type of the above-described pressure-sensitive adhesive layer. In general, the compounded amount is, for example, 5 to 500 parts by weight relative to 100 parts by weight of the base polymer such as an acrylic polymer constituting the pressure-sensitive adhesive, and preferably about 40 to 150 parts by weight.

The radiation-curing pressure-sensitive adhesive includes an internal radiation-curing pressure-sensitive adhesive using a base polymer having a carbon-carbon double bond in a polymer side chain, in a main chain or at the end of the main chain, in addition to the addition-type radiation-curing pressure-sensitive adhesive described above. The internal radiation-curing pressure-sensitive adhesive does not require incorporation of low-molecular components such as oligomer components etc., or does not contain such compounds in a large amount, and thus the oligomer components etc. do not move with time through the pressure-sensitive adhesive, thus preferably forming the pressure-sensitive adhesive layer having a stabilized layer structure.

As the base polymer having a carbon-carbon double bond, a polymer having a carbon-carbon double bond and exhibiting tackiness can be used without particular limitation. Such base polymer is preferably a polymer having an acrylic polymer as a fundamental skeleton. The fundamental skeleton of the acrylic polymer includes the acrylic polymer illustrated above.

The method of introducing a carbon-carbon double bond into the acrylic polymer is not particularly limited, and various methods can be used, and the introduction of the carbon-carbon double bond into a polymer side chain is easy in molecular design. There is, for example, a method that after a monomer having a functional group is copolymerized with the acrylic polymer, a compound having a carbon-carbon double bond and a functional group capable of reacting with the above functional group is subjected to condensation or addition reaction therewith while the radiation-curing properties of the carbon-carbon double bond is maintained.

A combination of these functional groups includes combinations of carboxylic acid group and epoxy group, carboxylic acid group and aziridyl group, or hydroxy group and isocyanate group. Among these combinations of functional groups, the combination of hydroxyl group and isocyanate group is preferable for easiness of monitoring the reaction. The functional groups may be present in either the acrylic polymer or the above compound insofar as a combination of the functional groups forms the acrylic polymer having a carbon-carbon double bond, and in the preferable combination described above, it is preferable that the acrylic polymer has a hydroxyl group, and the above compound has an isocyanate group. In this case, the isocyanate compound having a carbon-carbon double bond includes, for example, methacryloyl isocyanate, 2-methacryloyloxyethyl isocyanate, m-isopropenyl-α,α-dimethyl benzyl isocyanate. As the acrylic polymer, copolymers of the above-mentioned hydroxy group-containing monomer and an ether compound such as 2-hydroxyethyl vinyl ether, 4-hydroxy butyl vinyl ether or diethylene glycol monovinyl ether are used.

As the internal radiation-curing pressure-sensitive adhesive, the base polymer having a carbon-carbon double bond (particularly acrylic polymer) can be used solely, but the radiation-curing monomer component and the oligomer component can also be compounded to such an extent that the features of the pressure-sensitive adhesive are not deteriorated. The radiation-curable oligomer component, or the like, is in the range of 0 to 30 parts by weight relative to 100 parts by weight of a normal base polymer, and preferably in the range of 0 to 10 parts by weight.

For curing with UV rays, a photopolymerization initiator is incorporated into the radiation-curing pressure-sensitive adhesive. The photopolymerization initiator includes, for example, α-ketol compounds such as 4-(2-hydroxyethoxy)phenyl(2-hydroxy-2-propyl)ketone, α-hydroxy-α,α′-dimethyl acetophenone, 2-methyl-2-hydroxypropiophenone, 1-hydroxycyclohexyl phenyl ketone etc.; acetophenone compounds such as methoxyacetophenone, 2,2-dimethoxy-2-phenylacetophenone, 2,2-diethoxyacetophenone, 2-methyl-1-[4-(methylthio)-phenyl]-2-morpholinopropane-1 etc.; benzoin ether compounds such as benzoin ethyl ether, benzoin isopropyl ether, anisoin methyl ether etc.; ketal compounds such as benzyl dimethyl ketal etc.; aromatic sulfonyl chloride compounds such as 2-naphthalene sulfonyl chloride etc.; optically active oxime compounds such as 1-phenone-1,1-propanedione-2-(o-ethoxycarbonyl)oxime etc.; benzophenone compounds such as benzophenone, benzoylbenzoic acid, 3,3′-dimethyl-4-methoxybenzophenone etc.; thioxanthone compounds such as thioxanthone, 2-chlorothioxanthone, 2-methyl thioxanthone, 2,4-dimethyl thioxanthone, isopropyl thioxanthone, 2,4-dichlorothioxanthone, 2,4-diethyl thioxanthone, 2,4-diisopropyl thioxanthone etc.; camphor quinone; halogenated ketone; acyl phosphinoxide; acyl phosphonate etc. The amount of the photopolymerization initiator to be incorporated is for example about 0.05 to 20 parts by weight, based on 100 parts by weight of the base polymer such as acrylic polymer etc. constituting the pressure-sensitive adhesive.

The radiation-curing pressure-sensitive adhesive includes, for example, those disclosed in JP-A 60-196956, such as a rubber-based pressure-sensitive adhesive and an acrylic pressure-sensitive adhesive, comprising an addition-polymerizable compound having two or more unsaturated bonds, a photopolymerizable compound such as alkoxysilane having an epoxy group, and a photopolymerization initiator such as a carbonyl compound, an organic sulfur compound, a peroxide, an amine or an onium salt compound.

If necessary, the radiation-curing pressure-sensitive adhesive layer 2 can also contain a compound coloring upon irradiation with radiations. By incorporating the compound coloring upon irradiation with radiations into the pressure-sensitive adhesive layer 2, only a region irradiated with radiations can be colored. Accordingly, whether the pressure-sensitive adhesive layer 2 was irradiated with irradiations or not can be immediately judged by visual check, thus making the base film 1 and the pressure-sensitive adhesive layer 2 easily recognizable and facilitating attachment of the adhesive layer 3 and the spacer layer 4. Further, when a semiconductor element is to be detected with an optical sensor etc., its detection accuracy is increased and the semiconductor element can be picked up without error.

The compound coloring upon irradiation with radiations is a compound that is colorless or light-colored before irradiation with radiations and is colored upon irradiation with radiations. Preferable examples of such compounds include leuco dyes. As the leuco dyes, it is preferable to employ conventional leuco dyes based on triphenyl methane, fluoran, phenothiazine, auramine and spiropyran. Specific examples include 3-[N-(p-tolylamino)]-7-anilinofluoran, 3-[N-(p-tolyl)-N-methylamino]-7-anilinofluoran, 3-[N-(p-tolyl)-N-ethylamino]-7-anilinofluoran, 3-diethylamino-6-methyl-7-anilinofluoran, crystal violet lactone, 4,4′,4″-tris-dimethyl aminotriphenyl methanol, and 4,4′,4″-tris-dimethylaminotriphenyl methane.

A developer preferably used together with these leuco dyes includes electron acceptors such as conventionally used initial phenol formalin resin polymers, aromatic carboxylic acid derivatives, activated clay etc., and when the color tone is to be changed, a combination of various coloring agents can also be used.

The compound coloring upon irradiation with radiations may be dissolved once in an organic solvent or the like and then contained in the radiation-curing pressure-sensitive adhesive, or may be contained in a fine powdery form in the pressure-sensitive adhesive. It is desired that the amount of this compound to be used is 10 wt % or less, preferably 0.01 to 10 wt %, more preferably 0.5 to 5 wt %, based on the pressure-sensitive adhesive layer 2. When the amount of the compound is higher than 10 wt %, the compound absorbs considerable radiations with which the pressure-sensitive adhesive layer 2 is irradiated, resulting in insufficient curing of the pressure-sensitive adhesive thus failing to achieve sufficient reduction in adhesion in some cases. For sufficient coloration, on the other hand, the amount of the compound is preferably 0.01 wt % or more.

The thickness of the pressure-sensitive adhesive layer 2 is not especially limited. However, it is preferably about 1 to 50 μm in terms of compatibility of chipping prevention of the chip cut surface and maintaining of fixing the adhesive layer, more preferably 2 to 30 μm, and further preferably 5 to 25 μm.

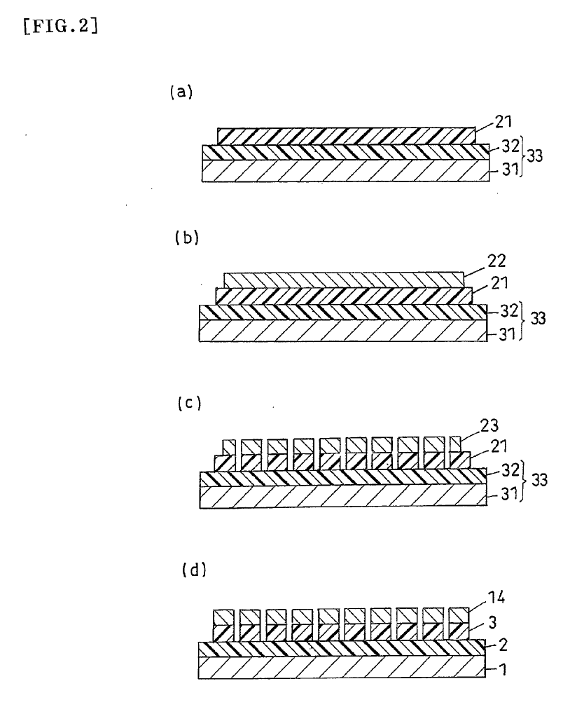

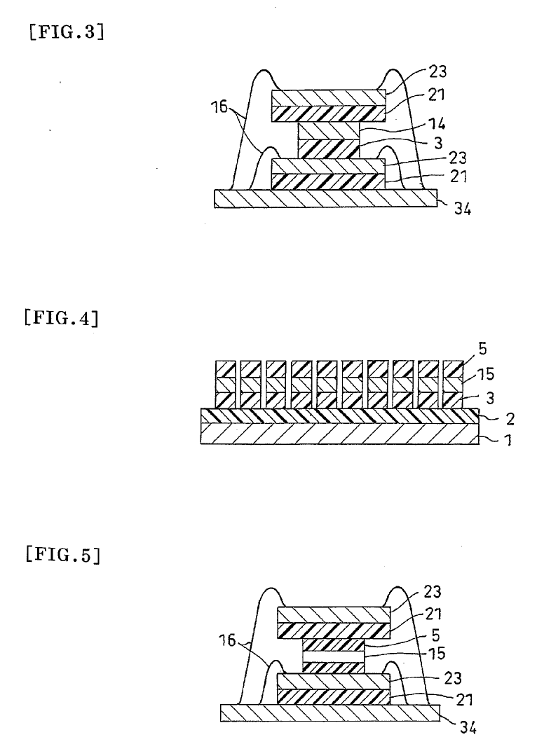

Next, the process for producing a semiconductor device according to the embodiment 1 is described with reference to FIGS. 2 and 3. FIG. 2 is a process view illustrating the process for producing a semiconductor device according to the present embodiment. FIG. 3 is a cross-sectional view showing an outline of the semiconductor device obtained by the process for producing a semiconductor device according to the present embodiment.

First, a dicing tape 33 is prepared having a configuration, in which a pressure-sensitive adhesive layer 32 is laminated on a supporting substrate 31. Next, a die bonding layer 21 made of an adhesive layer is laminated on this dicing tape 33 (FIG. 2(a)). Furthermore, a semiconductor wafer 22 is stuck onto the die bonding layer 21. Subsequently, this semiconductor wafer 22 is diced so as to become a prescribed size, to form a semiconductor chip 23. Next, the semiconductor chip 23 is peeled from the dicing tape 33 together with the die bonding layer 21. Thus, the semiconductor chip 23 provided with the die bonding layer 21 is obtained.

On the other hand, the adhesive sheet 10 shown in FIG. 1(a) is prepared, and a chip-shaped spacer 14 is formed by dicing the spacer layer 4 in this adhesive sheet 10. At this time, the size of the spacer 14 is made to be such that an electrode pad part (not shown in the figure) of the semiconductor chip 23 is not covered in the case that the spacer 14 is laminated on the semiconductor chip 23. Further, the dicing is preferably performed from the formation surface side of the spacer layer 4. A dicing equipment used in the present step is not especially limited, and a conventionally known equipment can be applied.

Moreover, in the case of using the adhesive sheet 12 shown in FIG. 1(c), the adhesive sheet 12 is preferably stuck with the dicing sheet before the dicing. A conventionally known dicing sheet can be used, and a specific example includes a dicing sheet, in which the pressure-sensitive adhesive layer 2 is laminated on the base film 1. The sticking is performed with the adhesive layer 3 in the adhesive sheet 12 as the sticking surface. The sticking condition can be set the same as the condition when the semiconductor wafer is stuck to the dicing sheet.

Next, the spacer 14 is picked up and peeled from the pressure-sensitive adhesive layer 2 together with the adhesive layer 3. The method of pickup is not especially limited, and various conventionally known methods and equipment can be applied. An example includes a method of raising each spacer 14 from the base film 1 side (the lower side) with a needle and picking up the raised spacer 14 with a pickup device. The pickup condition can be set the same as the condition when the semiconductor chip is picked up.

Next, the above-described semiconductor chip 23 is temporarily adhered onto an adherend 34 such as a substrate with the die bonding layer 21 interposed therebetween so that a wire bonding surface becomes the upper side. Subsequently, the spacer 14 is temporarily adhered onto the semiconductor chip 23 with the adhesive layer 3 interposed therebetween. Furthermore, another semiconductor chip 23 is temporarily adhered onto the spacer 14 with the die bonding layer 21 interposed therebetween.

The adherend 34 includes a substrate or a lead frame. Furthermore, a conventionally known substrate can be used as the substrate. The substrate may be any substrate known in the prior art. The lead frame may be a metal lead frame such as a Cu lead frame or a 42-alloy lead frame; or an organic substrate made of glass epoxy resin, BT (bismaleimide-triazine), polyimide or the like. In the present invention, however, the substrate is not limited to these substrates, and may be a circuit substrate that can be used in the state that a semiconductor element is mounted on the substrate itself and is electrically connected thereto.

The shearing adhesive strength of the adhesive layer 3 during the temporary fixing is preferably 0.2 MPa or more to the semiconductor chip 23 for example, and more preferably 0.2 to 10 MPa. Because the shearing adhesive strength of the adhesive layer 3 is at least 0.2 MPa or more, shearing deformation does not occur at the adhesive surface of the adhesive layer 3 with the spacer 14, the semiconductor chip 23, etc., due to the ultrasound wave vibration and heating in the step even when the wire bonding step is performed without a heating step. That is, the spacer 14 and the semiconductor chip 23 do not move due to the ultrasound wave vibration during wire bonding, and thus a successful rate of the wire bonding can be prevented from decreasing.

Next, the wire bonding step is performed. Thus, the electrode pad (not shown in the figure) in the semiconductor chip 23 and a land for an inner connection in the adherend 34 are electrically connected by a bonding wire 16 (refer to FIG. 3). A gold wire, an aluminum wire, a copper wire, or the like, can be used as the bonding wire 16 for example. The temperature when the wire bonding is performed is in the range of 80 to 250° C., and preferably in the range of 80 to 220° C. Further, its heating time is a few seconds to a few minutes. The connection is performed in the state of heating so as to be in the above-described temperature range by using the vibration energy due to the ultrasound wave and the compression energy due to pressure application together. Moreover, the present step may be performed before the semiconductor chip 23 at the upper side is temporarily adhered.

The present step is performed without adhesion by the die bonding layer 21 and the adhesive layer 3. Further, the semiconductor chip 23, the spacer 14, and the adherend 34 do not adhere with the die bonding layer 21 and the adhesive layer 3 in the process of the present step. Here, the shearing adhesive strength of the adhesive layer 3 is necessarily 0.2 MPa or more even in the temperature range of 80 to 250° C. When the shearing adhesive strength is less than 0.2 MPa in this temperature range, the semiconductor element moves due to the ultrasound vibration during wire bonding, the wire bonding cannot be performed, and the yield decreases.

Next, a sealing step of sealing the semiconductor element with a sealing resin is performed. Thereby, the sealing resin is cured, and at the same time, the adherend 34 and the semiconductor chip 23, and the semiconductor chip 23 and the spacer are fixed by the adhesive layer 3 and the die bonding layer 21. The present step is performed by molding the sealing resin with a mold. An epoxy resin is used as the sealing resin for example. The sealing is usually performed at a heating temperature of 175° C. for 60 to 90 seconds. However, the present invention is not limited to this, and curing can be performed at 165 to 185° C. for a few minutes. In the present invention, fixing by the spacer 14 is possible in the present step, and it can contribute to reduction of the number of production steps and reduction in the production period even in the case that the post curing step described later is not performed.

After the sealing step, a post curing step may be performed. Thus, the sealing resin that is insufficiently cured in the sealing step can be cured completely. Further, even in the case that the fixing by the adhesive layer 3 is not performed in the sealing step, the fixing by the adhesive layer 3 becomes possible together with the curing of the sealing resin in the present step. The heating temperature in the present step differs with the type of the sealing resin. However, the heating temperature is in the range of 165 to 185° C., and the heating time is about 0.5 to 8 hours. By performing the above-described production steps, the semiconductor device according to the present embodiment can be obtained.

### Embodiment 2

A process for producing a semiconductor device according to embodiment 2 is described with reference to FIGS. 4 and 5. FIG. 4 is a process view illustrating a dicing step of an adhesive sheet for a spacer that is used in an embodiment 2 of the present invention. FIG. 5 is a cross-sectional view showing an outline of the semiconductor device obtained by the process for producing a semiconductor using the adhesive sheet for a spacer.

The adhesive sheet according to the present embodiment differs as compared with the adhesive sheet according to the embodiment 1 in terms of using the adhesive sheet 11, in which another adhesive layer 5 is laminated also on the spacer layer 4 (refer to FIG. 1(b)).

A method of producing a chip-shaped spacer 15 from the adhesive sheet 11 is performed by dicing, in the same manner as in the embodiment 1. At this time, the size of the spacer 15 is made to be such that the electrode pad part of the semiconductor chip 23 is not covered, in the same manner as in the spacer 14 in the embodiment 1. The method of picking up the spacer 15 from the base film 1 and a method of fixing the spacer 15 onto the semiconductor chip 23 are performed in the same manner as in the embodiment 1.

Furthermore, in the same manner as in the embodiment 1, the semiconductor device shown in FIG. 5 can be obtained by performing the wire bonding step, the sealing step, and the post curing step.

### (Other Items)

In the case of three-dimensionally mounting a semiconductor chip onto the above-described adherend, a buffer coating film is formed on the surface side on which a semiconductor chip circuit is formed. Examples of the buffer coating film include a silicon nitride film and a buffer coating film made of a heat resistant resin such as a polyimide resin.

Further, the adhesive used at each step during the three-dimensional mounting of the semiconductor chip is not limited to an adhesive layer made of the same composition, and it can be changed appropriately depending on the production condition and the use.

Further, the laminating method described in the above-described embodiment is described as an example, and it can be changed appropriately depending on necessity.

Further, in the embodiment, a mode of laminating a plurality of the semiconductor chips on the adherend and then performing the wire bonding step by lumping it together is described. However, the present invention is not limited to this. For example, it is possible to perform the wire bonding step every time when the semiconductor chip is laminated on the adherend.

### EXAMPLES

Below, preferred examples of the present invention are explained in detail. However, materials, addition amounts, and the like described in these examples are not intended to limit the scope of the present invention, and are only examples for explanation as long as there is no description of limitation in particular. In the examples, the word “part(s)” represent “part(s) by weight”, respectively, unless otherwise specified.

### Example 1

### Production of Adhesive Sheet with Metal Foil

A multifunctional isocyanate crosslinking agent (3 parts), an epoxy resin (manufactured by Japan Epoxy Resins Co., Ltd., trade name: EPICOAT 1004) (23 parts), a phenol resin (manufactured by Mitsui Chemicals, Inc., trade name: MILEX XLC-LL) (6 parts), and an acrylic acid ester polymer (manufactured by Negami Chemical Industrial Co., Ltd., trade name: PARACRON W-197CM) (100 parts) containing ethyl acrylate-methyl methacrylate as a main component were dissolved into methyl ethyl ketone, and a solution of an adhesive composition having a concentration of 20% by weight was prepared.

The solution of this adhesive composition was applied onto a rolled steel foil (thickness 50 μm) as a metal foil. Furthermore, the foil was dried at 120° C. for 3 minutes to produce an adhesive sheet with a metal foil, in which the thickness of the adhesive layer becomes 25 μm (total thickness 75 μm).

### [Preparation of Radiation Curable Acrylic Adhesive]

Butyl acrylate (70 parts), ethyl acrylate (30 parts), and acrylic acid (5 parts) were copolymerized in ethyl acetate by a normal method, to obtain a solution of an acrylic polymer having a weight average molecular weight of 800,000 and a concentration of 30% by weight. Dipentaerythritolmonohydroxypenta acrylate (20 parts) as a photopolymerizable compound and α-hydroxycyclohexylphenyl ketone (1 part) as a photopolymerizing initiator were compounded into the acrylic polymer solution. These were dissolved uniformly into toluene, to produce a solution of a radiation curable acrylic pressure-sensitive adhesive having a concentration of 25% by weight.

[Production of Adhesive Sheet for Spacer]

The above-described solution of a radiation curable acrylic pressure-sensitive adhesive was applied onto a supporting substrate made of a polyethylene film having a thickness of 60 μm. Furthermore, the substrate was dried at 120° C. for 3 minutes, to form a pressure-sensitive adhesive layer having a thickness of 20 μm. Hereinafter, this layer is referred to as a pressure-sensitive adhesive film. Subsequently, an ultraviolet ray was irradiated only to a part where the adhesive sheet with the metal foil was stuck onto the pressure-sensitive adhesive layer of the pressure-sensitive adhesive film at 500 ml/cm² (ultraviolet ray radiation integrated light amount), to obtain a film having a pressure-sensitive adhesive layer in which the part corresponding the sticking of the adhesive sheet with a metal foil was cured with radiation. Moreover, an ultraviolet ray (UV) irradiation device produced by Nitto Seiki Co., Ltd. (trade name: NELUM-110) was used for the ultraviolet irradiation.

Subsequently, the pressure-sensitive adhesive film and the adhesive sheet were stuck together so that the pressure-sensitive adhesive layer side of the pressure-sensitive adhesive film and the adhesive layer side of the adhesive sheet with a metal foil became a sticking surface, and an adhesive sheet for a spacer according to the embodiment 1 was produced.

### Example 2

An adhesive sheet with a metal foil (thickness of the adhesive layer 25 μm, thickness of the adhesive sheet with a metal foil 75 μm) according to Example 2 was produced in the same manner as in Example 1 except that a polymer (manufactured by Negami Industrial Co., Ltd., PARACRON SN-710) containing butyl acrylate as a main component was used in Example 2 in place of the acrylic acid ester polymer used in Example 1, and an adhesive sheet for a spacer according to Example 2 was produced.

### Example 3

An adhesive sheet with a metal foil (thickness of the adhesive layer 25 thickness of the adhesive sheet with a metal foil 75 μm) according to Example 3 was produced in the same manner as in Example 1 except that a stainless steel foil was used in Example 3 in place of the rolled steel foil used in Example 1, and an adhesive sheet for a spacer according to the 3 was produced.

### Example 4

An adhesive sheet for a spacer according to Example 4 was produced in the same manner as in Example 3 except that the thickness of the stainless steel foil used in Example 3 was changed to 25 μm from 50 μm and the thickness of the adhesive sheet with a metal foil was made to 50 μm.

### Comparative Example 1

An adhesive sheet for a spacer according to the present Comparative Example 1 was produced in the same manner as in Example 1 except that a peeling sheet was used in Comparative Example 1 in place of the rolled steel foil used in Example 1.

### Comparative Example 2

In Comparative Example 2, a polymer (manufactured by Negami Industrial Co., Ltd., PARACRON SN-710) containing butyl acrylate as a main component was used in place of the acrylic acid ester polymer used in Example 2. An adhesive sheet for a spacer according to Comparative Example 2 was produced in the same manner as in Comparative Example 1.

### (Dicing)

Dicing of each adhesive sheet for a spacer produced in Examples 1 to 4 and Comparative Examples 1 and 2 was performed using Dicer DFD 651 manufactured DISCO Cooperation. At this time, the dicing was performed so that a chip-shaped spacer with a size of 10 mm×10 mm can be obtained. During dicing, the dicing was performed on all samples without any problem such as chipping. The dicing condition was as described below.

### [Dicing Condition]

Equipment: Dicer DFD651 manufactured DISCO Cooperation

Dicing Speed: 50 mm/sec

Dicing Blade: 2050-SE27HECC manufactured by Disco Cooperation

Dicing Blade Rotation Speed: 40000 rpm

Adhesive Sheet Cutting Depth: 85 μm

Size of Chip-Shaped Space: 10 mm×10 mm

### (Pickup)

The pickup was performed on the adhesive sheet for a spacer after dicing, and 20 chip-shaped spacers were produced. Die Bonder SPA300 manufactured Shinkawa Ltd., that is used during the pickup of a semiconductor chip was used in the pickup. Further, the condition of pickup was made to be as described below. Furthermore, the success rate of the pickup was calculated in the present step. Its result is shown in Table 1 below.

### [Pickup Condition]

Pickup Equipment Die Bonder SPA300 manufactured by Shinkawa Inc.

Number of Needles: 5 to 9 needles

Push-Up Amount: 300 μm

Push-Up Speed: 80 mm/sec

Pull-Down Amount: 3 mm

Heating after Pull-Down: None

### (Result)

As shown in Table 1 below, any of the success rates of pickup in the adhesive sheet for a spacer according to Examples 1 to 4 was 100%, and contrarily, any of the success rates of pickup in the adhesive sheet for a spacer according to Comparative Examples 1 and 2 was 0%. Therefore, the pickup by a conventional pickup device is impossible in the adhesive sheet for a spacer in Comparative Examples 1 and 2, and contrarily, it was confirmed that in the adhesive sheet for a spacer in Examples 1 to 4, the pickup can be performed with a good yield even with the conventional pickup equipment without novel pickup equipment that is appropriate being necessary.

TABLE 1

| | Dicing | pickup |
|---|---|---|
| Example 1 | good | 100% |
| Example 2 | good | 100% |
| Example 3 | good | 100% |
| Example 4 | good | 100% |
| Comparative Example 1 | good | 0% |
| Comparative Example 2 | good | 0% |

1. A process for producing a semiconductor device using an adhesive sheet for a spacer, comprising preparing an adhesive sheet having a spacer layer provided with an adhesive layer on at least one surface thereof as the adhesive sheet for a spacer, a step of sticking the adhesive sheet for a spacer onto a dicing sheet with the adhesive layer as a sticking surface, a step of dicing the adhesive sheet for a spacer to form a chip-shaped spacer provided with the adhesive layer, a step of peeling the spacer from the dicing sheet together with the adhesive layer, and a step of fixing the spacer onto an adherend with the adhesive layer interposed therebetween.

2. The process for producing a semiconductor device according to claim 1, wherein the adhesive sheet for a spacer, in which the spacer layer is a metal layer, is used.

3. The process for producing the semiconductor device according to claim 1, wherein the object is a substrate, a lead frame or a semiconductor element.

4. The process for producing a semiconductor device according to claim 1, wherein the adhesive layer is configured by including a thermoplastic resin.

5. The process for producing the semiconductor device according to claim 4, wherein an acrylic resin is used as the thermoplastic resin.

6. The process for producing a semiconductor device according to claim 1, wherein the adhesive layer is configured by including a thermosetting resin and a thermoplastic resin.

7. The process for producing the semiconductor device according to claim 6, wherein an acrylic resin is used as the thermoplastic resin.

8. An adhesive sheet for a spacer used in the process for producing a semiconductor device according to claim 1.

9. A semiconductor device produced by the method according to claim 1.

10. A process for producing a semiconductor device using an adhesive sheet for a spacer, comprising preparing a sheet, in which a pressure-sensitive adhesive layer, an adhesive layer, and a spacer layer are laminated one by one, for the adhesive sheet for a spacer, a step of dicing the adhesive sheet for a spacer to form a chip-shaped spacer provided with the adhesive layer, a step of peeling the spacer from the pressure-sensitive adhesive layer together with the adhesive layer, and a step of fixing the spacer onto an adherend with the adhesive layer interposed therebetween.

11. The process for producing a semiconductor device according to claim 10, wherein the adhesive sheet for a spacer, in which the spacer layer is a metal layer, is used.

12. The process for producing the semiconductor device according to claim 10, wherein the object is a substrate, a lead frame or a semiconductor element.

13. The process for producing a semiconductor device according to claim 10, wherein the adhesive layer is configured by including a thermoplastic resin.

14. The process for producing the semiconductor device according to claim 13, wherein an acrylic resin is used as the thermoplastic resin.

15. The process for producing a semiconductor device according to claim 10, wherein the adhesive layer is configured by including a thermosetting resin and a thermoplastic resin.

16. The process for producing the semiconductor device according to claim 15, wherein an acrylic resin is used as the thermoplastic resin.

17. An adhesive sheet for a spacer used in the process for producing a semiconductor device according to claim 10.

18. A semiconductor device produced by the method according to claim 10.

19. The process for producing a semiconductor device according to claim 1, wherein the shearing adhesive strength of the adhesive layer to the adherend is 0.2 to 10 MPa.

20. The process for producing a semiconductor device according to claim 10, wherein the pressure-sensitive adhesive layer comprises a radiation-curable pressure-sensitive adhesive.

21. A process for producing a semiconductor device attached to a spacer-containing adhesive sheet, comprising:
providing an adhesive sheet, wherein said adhesive sheet comprises a spacer layer and an adhesive layer on at least one surface of the spacer layer;
sticking the adhesive sheet onto a dicing sheet, wherein the adhesive layer of the adhesive sheet contacts the dicing sheet;
dicing the adhesive sheet to form chip-shaped spacers with adhesive, wherein said dicing is performed using semiconductor chip dicing equipment;
separating a chip-shaped spacer with adhesive from the dicing sheet; and
fixing the chip-shaped spacer with adhesive onto an adherend, wherein the adhesive of the chip-shaped spacer with adhesive contacts the adherend.
